(19) United States
(12) Patent Application Publication
(10) Pub. No.: US 2007/0013054 A1
(43) Pub. Date: Jan. 18, 2007

(54) Thermally conductive materials, solder preform constructions, assemblies and semiconductor packages

(76) Inventors: Brian D. Ruchert, Newman Lake, WA (US); Martin W. Weiser, Liberty Lake, WA (US); Mark B. Fery, Spokane, WA (US); Nancy F. Dean, Liberty Lake, WA (US); John N. Lalena, Fairchild AFB, WA (US)

Correspondence Address: Sandra Poteat Thompson;Buchalter Nemer, A Professional Law Corporation, Suite 800, 18400 Von Karman, Irvine, CA, 92612, US

(21) Appl. No.: 11/180,459

(22) Filed: Jul. 12, 2005

(51) Int. Cl. H01L 23/34

(52) U.S. Cl. 257/706

(57) ABSTRACT

A thermally conductive material that includes an alloy which includes indium, zinc, magnesium or a combination thereof is described herein. Also, a semiconductor package comprising a thermal interface material which includes solder and particles dispersed throughout the solder, the particles being of thermal conductivity greater than or equal to about 80 W/m-K is described herein. In one described embodiment, a semiconductor package includes a thermal interface material which includes at least one lanthanide element. In yet another embodiment disclosed herein, a solder preform construction includes a solder and a structure within the solder, the solder being of a first composition and the structure being of a second composition which has a lower melting point than the first composition. In another embodiment disclosed herein, an assembly comprising: a heat spreader; and a solder preform construction bonded to the heat spreader, the solder preform construction including a solder of a first composition, and a region within the solder of a second composition which has a lower melting point than the first composition. Methods of forming layered thermal interface materials and thermal transfer materials include: a) providing a heat spreader component, wherein the heat spreader component comprises a top surface, a bottom surface and at least one heat spreader material; b) providing at least one solder material, wherein the solder material is directly deposited onto the bottom surface of the heat spreader component; and c) depositing the at least one solder material onto the bottom surface of the heat spreader component.

### FIELD OF THE SUBJECT MATTER

The subject matter herein relates to thermally conductive materials, solder preform constructions, assemblies and semiconductor packages.

### BACKGROUND

Electronic components are used in ever increasing numbers of consumer and commercial electronic products. Examples of some of these consumer and commercial products are televisions, personal computers, Internet servers, cell phones, pagers, palm-type organizers, portable radios, car stereos and remote controls. As the demand for these consumer and commercial electronics increases, there is also a demand for those same products to become smaller, more functional, more cost efficient and thermally efficient, and more portable for consumers and businesses.

As a result of the size decrease in these products, the components that comprise the products must also become smaller, better manufactured and better designed. Examples of some of those components that need to be reduced in size or scaled down are printed circuit or wiring boards, resistors, wiring, keyboards, touch pads, and chip packaging.

Components, therefore, are being broken down and investigated to determine if there are better building materials and methods that will allow them to be scaled down and/or combined to accommodate the demands for smaller electronic components. In layered components, one goal appears to be decreasing the number of the layers while at the same time increasing the functionality and durability of the remaining layers, decreasing the production steps and increasing the cost efficiency. These tasks can be difficult, however, given that the number of layers cannot readily be reduced without sacrificing functionality.

The high speed and integration associated with modern semiconductor dies or dice (also called chips) generates large amounts of heat within the dies. Thus, substantial effort is directed toward developing designs for semiconductor die packaging which can adequately conduct heat away from a semiconductor die during operation of the die. Such designs typically have the die provided proximate a heat spreader, which can be, for example, a metallic plate. However, differences in thermal expansion between the materials of the heat spreader and the semiconductor die can cause the die to crack if it directly contacts the heat spreader.

A popular practice in the industry is to use thermal grease, or grease-like materials, alone or on a carrier in such devices to transfer the excess heat dissipated across physical interfaces. The most common types of thermal interface materials are thermal greases, phase change materials, and elastomer tapes. Thermal greases or phase change materials have lower thermal resistance than elastomer tape because of the ability to be spread in very thin layers and provide intimate contact between adjacent surfaces. Typical thermal impedance values range between 0.1-1.6° C. cm²/W. However, a serious drawback of thermal grease is that thermal performance deteriorates significantly after thermal cycling, such as from −65° C. to 150° C., or after power cycling when used in VLSI chips. It has also been found that the performance of these materials deteriorates when large deviations from surface planarity causes gaps to form between the mating surfaces in the electronic devices, or when large gaps between mating surfaces are present for other reasons, such as manufacturing tolerances, etc. When the heat transferability of these materials breaks down, the performance of the electronic device in which they are used is adversely affected.

Moore's law states that the number of transistors on a silicon die will double every 18 months. This occurs partially through smaller electrical traces allowing more transistors per unit area across a semiconductor die, and results in modern highly-integrated semiconductor dies generating large amounts of heat per unit area. Removing this heat is problematic. Organic pastes with metallic fillers have historically been used to remove heat from semiconductor dies. However, organic pastes generally cannot remove much over 8 watt/m-K (W/m-K). To remove the level of heat generated by the present generation of semiconductor dies, it is desired to have a thermal conductance at least about five-fold higher than that typically achievable with organic pastes. Metal solders can meet the requirement of having a higher thermal conductance and are presently being used as die attach materials. Indium is one preferred solder since it has a very low melting point (156 C), has very low yield strength (and therefore does not cause mechanical stress to the die) and has a thermal conductivity of 84 W/m-K.

Organic pastes and epoxies are also being used to facilitate heat removal from the component. One example of this use is applying the organic paste and/or epoxy to the interface between the silicon and a heat spreader, such as a nickel plated copper spreader. These pastes and epoxies are normally filled with metal or other thermally conductive particles to improve heat transfer. As components are becoming smaller and more complex, the amount of heat to be removed has increased to the point where solid metal thermal interface is necessary. In most conventional applications, the solid metal thermal interface is a solder material of melting point 140-200° C.

As more solder materials are being utilized in components to dissipate heat, it has been discovered that it is difficult to solder to nickel without the use of a material, such as a flux, because of the production of detrimental nickel oxides at the solder-nickel interface. One recent approach to completing the solder joint without the use of a flux is to electrodeposit a gold spot on the precise location where the solder joint is to be formed. This approach is described in U.S. Pat. No. 6,504,242 issued to Deppisch et al. (Jan. 7, 2003). While this approach works well functionally, the value of gold contained within the spot is detrimental to the cost efficiency of the components. Furthermore, in order to complete a joint having a gold spot or gold interface, there are at least two process steps necessary—deposition of the gold and application of the solder material. These additional process steps are not only costly, but slow.

A thermal interface material should ideally be a relatively compliant material at the operating temperatures of the semiconductor die (typically such operating temperature is from about 80° C. to about 100° C.), should have a low modulus, and should make good thermal contact with both a heat spreader and a semiconductor die surface without providing significant metallization along the die surface.

It can be particularly important that the thermal interface material be relatively compliant at the operating temperatures of the semiconductor die, as such can enable the thermal interface material to accommodate the different thermal expansion characteristics of the die on one side of the material and the heat spreader on the other side of the material. The thermal interface material can be rendered compliant by providing the material to have a relatively low melting temperature so that the material is not fully mechanically rigid at the operating temperatures of the die. The melting temperature should, however, typically be higher than the operating temperature of the semiconductor die so that the thermal interface material does not become liquid during operation of the semiconductor die.

In addition to being compliant, it can be beneficial for the thermal interface material to have a coefficient of thermal expansion that is between the coefficient of thermal expansion of the semiconductor die that is on one side of the thermal interface material, and the coefficient of thermal expansion of the heat spreader that is on the other side of the thermal interface material. This can further enable the thermal interface material to accommodate the different expansion characteristics of the die and the heat spreader.

Another application for thermal interface materials in semiconductor packaging is to provide the materials between a heat spreader and a heat sink. The heat spreader will typically be utilized for taking heat generated at discrete locations of a semiconductor die and spreading it over a larger surface area. The heat sink will be thermally coupled with the heat spreader and will be utilized for taking the heat from the spreader and diffusing it into the environment around the semiconductor package. The heat sink can be formed of a different material than the heat spreader, and accordingly can have a different coefficient of thermal expansion than the heat spreader. Accordingly, a thermal interface material can be provided between the heat sink and the heat spreader to avoid cracking and other problems that could otherwise occur if the heat spreader and heat sink directly contacted one another.

Dispersion of heat from semiconductor devices during operation of the devices is of significant importance, and is becoming of increasing importance as the level of integration within the devices increases. Thermal interface materials are important components for heat dispersion in semiconductor packaging, and accordingly it is desired to develop improved thermal interface materials.

Thus, there is a continuing need to: a) design and produce thermal interconnects and thermal interface materials, layered materials, components and products that meet customer specifications while minimizing the size of the device and number of layers; b) produce more efficient and better designed materials, products and/or components with respect to the compatibility requirements of the material, component or finished product; c) develop reliable methods of producing desired thermal interconnect materials, thermal interface materials and layered materials and components/products comprising contemplated thermal interface and layered materials; d) develop materials that possess a high thermal conductivity and a high mechanical compliance; e) develop materials that are provided as deformable heat-conducting bridges between dies and heat spreaders; and f) effectively reduce the number of production steps necessary for a package assembly, which in turn results in a lower cost of ownership over other conventional layered materials and processes.

### SUMMARY OF THE SUBJECT MATTER

A thermally conductive material that includes an alloy which includes indium, zinc, magnesium or a combination thereof is described herein.

Also, a semiconductor package comprising a thermal interface material which includes solder and particles dispersed throughout the solder, the particles being of thermal conductivity greater than or equal to about 80 W/m-K is described herein.

In one described embodiment, a semiconductor package includes a thermal interface material which includes at least one lanthanide element.

In yet another embodiment disclosed herein, a solder preform construction includes a solder and a structure within the solder, the solder being of a first composition and the structure being of a second composition which has a lower melting point than the first composition.

In another embodiment disclosed herein, an assembly comprising: a heat spreader; and a solder preform construction bonded to the heat spreader, the solder preform construction including a solder of a first composition, and a region within the solder of a second composition which has a lower melting point than the first composition.

Methods of forming layered thermal interface materials and thermal transfer materials include: a) providing a heat spreader component, wherein the heat spreader component comprises a top surface, a bottom surface and at least one heat spreader material; b) providing at least one solder material, wherein the solder material is directly deposited onto the bottom surface of the heat spreader component; and c) depositing the at least one solder material onto the bottom surface of the heat spreader component.

In yet another method of forming layered thermal interface materials and thermal transfer materials, these methods include: a) providing a heat spreader component, wherein the heat spreader component comprises a top surface, a bottom surface and at least one heat spreader material; b) providing at least one solder preform, wherein the solder preform construction including a solder of a first composition, and a region within the solder of a second composition which is eutectic with the first composition; and c) coupling the at least one solder preform onto the bottom surface of the heat spreader component.

### BRIEF DESCRIPTION OF THE DRAWINGS

FIG. 1 is a diagrammatic, cross-sectional view of a contemplated semiconductor package which can be utilized in accordance with contemplated embodiments of the present subject matter.

FIG. 2 is a diagrammatic, cross-sectional view of an expanded region of the semiconductor package of FIG. 1. The region of FIG. 1 that is shown in FIG. 2 is labeled 2 in FIG. 1.

FIG. 3 is a diagrammatic, cross-sectional view of a contemplated particle construction that can be utilized in some embodiments of the subject matter.

FIG. 4 is a diagrammatic, cross-sectional view of a solder preform construction at a preliminary processing stage of a contemplated embodiment of the present subject matter.

FIG. 5 is a top view of the FIG. 4 solder preform construction, with the view of FIG. 4 being along the line 4-4 of FIG. 5.

FIG. 6 is a view of the solder preform of FIG. 4 shown at a processing stage subsequent to that of FIG. 4.

FIG. 7 is a view of the solder preform of FIG. 4 shown at a processing stage subsequent to that of FIG. 6.

FIG. 8 is a diagrammatic, cross-sectional view of an assembly comprising a heat spreader bonded to a solder preform construction.

FIG. 9 is a diagrammatic, cross-sectional view of a solder preform construction illustrating additional contemplated embodiments of the present subject matter.

FIG. 10 shows a DSC at 2° C./min for In3Ag1.5Cu and In6Ag3Cu.

FIG. 11 shows a DSC at 10° C./min for In6Ag3Cu.

### DETAILED DESCRIPTION

A suitable interface material or component should conform to the mating surfaces (“wets” the surface), possess a low bulk thermal resistance and possess a low contact resistance. Bulk thermal resistance can be expressed as a function of the material's or component's thickness, thermal conductivity and area. Contact resistance is a measure of how well a material or component is able to make contact with a mating surface, layer or substrate. The thermal resistance of an interface material or component can be shown as follows:
Θinterface=t/kA+2Θ_{contact} Equation 1
where
   Θ is the thermal resistance,
   t is the material thickness,
   k is the thermal conductivity of the material
   A is the area of the interface

The term “t/kA” represents the thermal resistance of the bulk material and “2Θ_{contact}” represents the thermal contact resistance at the two surfaces. A suitable interface material or component should have a low bulk resistance and a low contact resistance, i.e. at the mating surface.

Many electronic and semiconductor applications require that the interface material or component accommodate deviations from surface flatness resulting from manufacturing and/or warpage of components because of coefficient of thermal expansion (CTE) mismatches. A material with a low value for k, such as thermal grease, performs well if the interface is thin, i.e. the “t” value is low. If the interface thickness increases by as little as 0.002 inches, the thermal performance can drop dramatically. Also, for such applications, differences in CTE between the mating components causes the gap to expand and contract with each temperature or power cycle. This variation of the interface thickness can cause pumping of fluid interface materials (such as grease) away from the interface.

Interfaces with a larger area are more prone to deviations from surface planarity as manufactured. To optimize thermal performance, the interface material should be able to conform to non-planar surfaces and thereby lower contact resistance. Optimal interface materials and interconnect materials and/or components possess a high thermal conductivity and a high mechanical compliance, e.g. will yield elastically when force is applied. High thermal conductivity reduces the first term of Equation 1 while high mechanical compliance prevents interfacial damage which increases the second term.

As mentioned earlier, several goals of layered interface materials and individual components described herein are to: a) design and produce thermal interconnects and thermal interface materials, layered materials, components and products that meet customer specifications while minimizing the size of the device and number of layers; b) produce more efficient and better designed materials, products and/or components with respect to the compatibility requirements of the material, component or finished product; c) develop reliable methods of producing desired thermal interconnect materials, thermal interface materials and layered materials and components/products comprising contemplated thermal interface and layered materials; d) develop materials that possess a high thermal conductivity and a high mechanical compliance; e) develop materials that are provided as deformable heat-conducting bridges between dies and heat spreaders; and f) effectively reduce the number of production steps necessary for a package assembly, which in turn results in a lower cost of ownership over other conventional layered materials and processes.

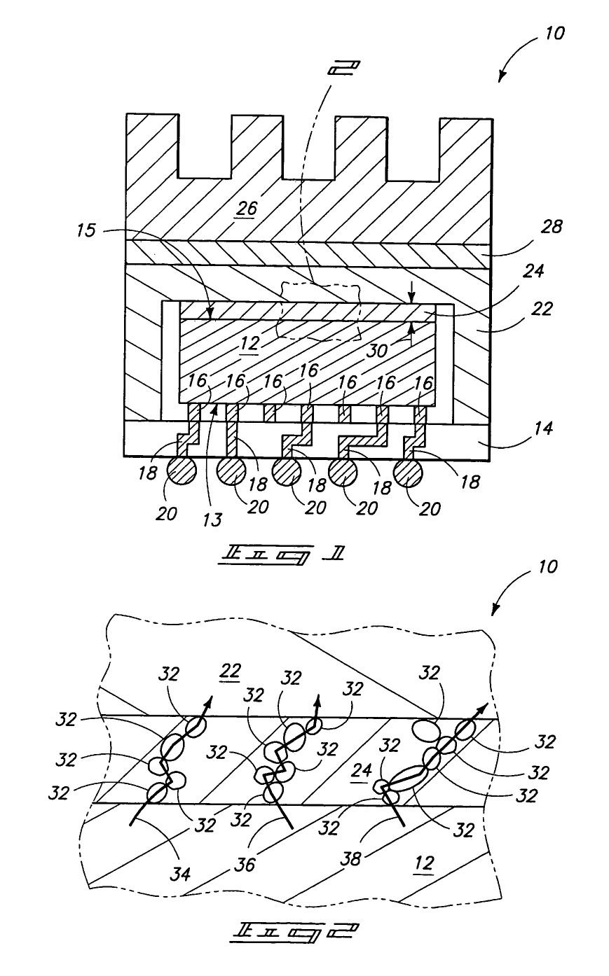

FIG. 1 shows a contemplated semiconductor package 10 illustrating exemplary aspects of the present subject matter. The package 10 comprises a semiconductor die 12 supported by a board 14. The die has a plurality of connections 16 extending to the board, and the board has a plurality of electrical interconnects 18 extending therethrough. The interconnects 18 extend to solder balls or bumps 20 on an external surface of the board. The solder balls or bumps can be utilized for electrically connecting the board to other circuitry (not shown). The electrical interconnects 18 and 16 connect the solder bumps to circuitry associated with semiconductor die 12. The interconnects 16 can comprise any of numerous interconnects known in the art, including, for example, solder bumps, gold stud bumps, column bumps, etc.

A heat spreader 22 is provided around die 12, and a thermal interface material 24 is provided between the die and the heat spreader. Additionally, a heat sink 26 is provided externally of the heat spreader, and a thermal interface material 28 is provided between the heat sink and the heat spreader. The thermal interface material 24 can be referred to as Thermal Interface Material 1 (TIM1), and the thermal interface material 28 can be referred to as Thermal Interface Material 2 (TIM2).

As discussed, the semiconductor die 12 can generate a significant amount of heat at various locations of the die, and the heat spreader 22 is utilized to disperse the heat across a wider area. Such dispersed heat is then transferred to the heat sink 26 and ultimately is transferred to an environment surrounding package 10.

The thermal interface materials 24 and 28 provide thermally-conductive interconnecting bridges between materials having different coefficients of thermal expansion. Specifically, thermal interface material 24 provides a thermally-conductive bridge between semiconductor die 12 and heat spreader 22; and thermal interface material 28 provides a thermally-conductive bridge between heat spreader 22 and heat sink 26.

Typically, semiconductor die 12 will be considered to have a front surface 13 proximate to board 14, and a back surface 15 in opposing relation to the front surface. The back surface 15 can comprise silicon or other semiconductor materials. Also typically, heat spreader 22 will comprise a metal having a very high thermal conductivity, such as, for example, copper, nickel-plated copper or composites designed for high conductivity. The back surface 15 of semiconductor die 12 will have a substantially different coefficient of thermal expansion than the heat spreader 22, and accordingly the thermal interface material 24 is provided to alleviate cracking and/or other problems that could occur if the materials 22 and 12 directly contact one another during heating of such materials. Similarly, heat sink 26 will typically comprise a different material than heat spreader 22, and can, for example, comprise aluminum. The thermal interface material 28 is provided between heat sink 26 and heat spreader 22 to alleviate cracking and/or other problems that can occur if such materials having different coefficients of thermal expansion are rigidly bonded to one another during heating and cooling of the materials.

The present subject matter includes improved thermal interface materials which can be utilized for any suitable application, including, for example, as one or both of the thermal interface materials 24 and 28 of the package 10.

In some aspects, the subject matter includes indium-based solders comprising zinc (from greater than 0 weight percent to less than or equal to about 5 weight percent) and magnesium (from greater than 0 weight percent to less than or equal to about 0.5 weight percent), that are particularly suitable as thermal interface materials. Such solders can comprise, for example, greater than 90 weight percent indium, about 1 weight percent zinc, and less than or equal to about 1000 ppm magnesium. The indium has a low modulus and high thermal conductivity; the zinc can improve high temperature corrosion resistance; and the magnesium can improve wetting and bonding to silicon nitride that may be along a surface of semiconductor die. The solders can include one or both of silver and tin in addition to the indium, zinc and magnesium.

A contemplated method of forming an indium-based alloy comprising zinc and magnesium is to mix pieces of zinc, magnesium and indium in a graphite crucible; melt them into a mixture at a temperature of at least 150° C. (with the temperature typically being from about 150° C. to about 350° C.); pour the molten mixture into a mold of desired shape; cool the mixture into a solid; and then work the cooled mixture by conventional metal working techniques (for example rolling and/or extrusion) as desired.

In particular aspects, the subject matter includes thermal interface materials comprising solder and particles dispersed throughout the solder, with the particles being of thermal conductivity greater than or equal to about 80 W/m-K and preferably greater than or equal to about 200 W/m-K. The particles preferably have a maximum dimension less than the thickness of a thermal interface material in an intended application of the interface material. For instance, the thermal interface material 24 of FIG. 1 has a thickness 30 from back side surface 15 of the semiconductor die to a surface of heat spreader 22. Such thickness is typically less than 0.010 inches, and frequently less than 0.005 inches. Accordingly, the particles utilized in the solder for thermal interface material 24 would preferably have a maximum dimension of less than or equal to 0.005 inches in applications in which the thermal interface material is going to be greater than 0.005 inches, and typically will have a maximum dimension of less than 0.002 inches, or even less than 0.001 inches for various applications.

The solder utilized for the thermal interface material can be any suitable solder, and can, for example, comprise one or more of indium, bismuth, magnesium, silver, tin and zinc. For instance, a contemplated solder can be the solder comprising indium, zinc and magnesium discussed above. As another example, a suitable solder can comprise, consist essentially of, or consist of indium and bismuth. The bismuth can be present to a concentration of greater than 0 weight percent and less than or equal to about 50 weight percent, with a typical concentration of the bismuth being from about 5 weight percent to about 50 weight percent. A typical composition of the solder has about 67 weight percent indium and about 33 weight percent bismuth.

Another contemplated solder comprises and/or consists essentially of indium and silver, with the silver being present to a concentration of from about 2 weight percent to about 25 weight percent. A typical composition of the solder has about 97 weight percent indium and about 3 weight percent silver.

Another contemplated solder comprises and/or consists essentially of indium, tin and zinc; with the zinc being present to a concentration of from about 1 weight percent to about 10 weight percent, the indium being present to a concentration of from about 5 weight percent to about 50 weight percent, and the tin being present to a concentration of from about 40 weight percent to about 96 weight percent. A typical composition of the solder can contain about 5 weight percent zinc, about 25 weight percent indium, and about 70 weight percent tin.

The particles utilized in the solder can be of any composition having the desired thermal conductivity greater than 80 W/m-K. In particular aspects, the particles can comprise, consist essentially of, or consist of one or more of aluminum, carbon, copper, nickel and silver. If the particles consist essentially of carbon, or consist of carbon, the carbon can be in either graphite form or diamond form.

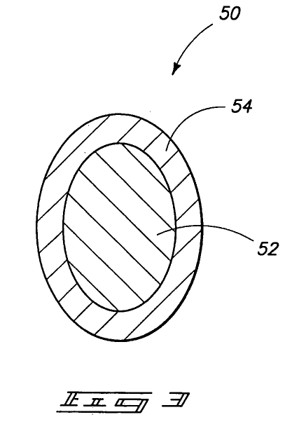

The particles utilized in the solder should be stable to the composition of the thermal interface material at the temperatures in which the thermal interface material is applied, and also at the operating temperatures of the thermal interface material. In other words, it is desired that the particles remain as discrete particles in the thermal interface material rather than breaking down and dispersing throughout the thermal interface material. If the particles remain as discrete particles, they can provide a path for thermal energy to migrate through the thermal interface material by jumping from one particle to another across the thickness of the thermal interface material. In contrast, if the particles break down and disperse throughout the solder, the solder will end up with a homogeneous composition of uniform thermal conductivity, and will not have separate paths extending therethrough for conducting thermal energy across it's thickness. FIG. 2 shows an expanded region of the FIG. 1 package, and shows a plurality of particles 32 providing paths 34, 36 and 38 for thermal energy to migrate through the thermal interface material 24.

Several techniques can be utilized to provide particles which are stable within the composition of the thermal interface material. In some aspects, particles can be chosen to be of a composition which does not interact with the solder utilized in the thermal interface material. For instance, the particles may comprise or consist essentially of silver or aluminum in aspects in which the solder contains indium and bismuth.

However, in some embodiments, there can be some dissolution of the particles. For instance, the silver may undergo some dissolution in a solder containing indium and bismuth. Accordingly, it can also be desirable to provide some spiking of the composition of the particles within the solder in order to create equilibrium conditions within the solder which avoid significant dissolution of the particles. In other words, the particles can comprise a metallic component in elemental form, and the solder can be formed to comprise an alloy substantially saturated with the component in order to avoid dissolution of the component from the particles. For instance, if the particles consist essentially of, or consist of silver, it can be advantageous to provide sufficient silver in the solder alloy to alleviate, and preferably prevent, substantial dissolution of silver from the particles. The amount of silver provided in the solder alloy can be enough to approximately reach the eutectic mixture of the silver within the solder composition. For instance, if the solder consists essentially of, or consists of a mixture of silver and indium, the silver can be provided to a concentration of about 3 weight percent.

Another technique for alleviating dissolution of particles within the solder is to plate the particles (or otherwise cover the particles) with a coating that is resistant to dissolution in the solder. For instance, FIG. 3 shows a contemplated particle 50 having a thermally conductive core 52 of a first composition, and a coating 54 surrounding the conductive core and having a different composition than the core.

In some embodiments, the core can be formed of a material having a very high thermal conductivity, but also having a tendency to dissolve in the solder of the thermal interface material; and the conductive coating can be formed of material having a lower thermal conductivity but a higher resistance to dissolving in the solder of the thermal interface material. In additional, or alternative embodiments, the coating comprises a material that is relatively wettable by the solder as compared to the material of the core. In some embodiments, the core can comprise, consist essentially of, or consist of at least one of aluminum, carbon, copper and silver; and the coating can comprise, consist essentially of, or consist of nickel.

The concentration of particles within the thermal interface material can be any suitable concentration to obtain desired thermal conductivity through the thermal interface material. In some embodiments, the concentration of particles within the thermal interface material can be from about 5 volume percent to about 75 volume percent.

Another aspect of the subject matter is to improve wetability of a thermal interface material on one or both of the surfaces in direct contact with the thermal interface material. For instance, to improve wetability of the thermal interface material 24 on one or both of the back side surface 15 of die 12 and the surface of heat spreader 22; or to improve wetability of thermal interface material 28 on one or both of the surface of heat spreader 22 and the surface of heat sink 26.

The improvement in wetability can accomplished by including one or more lanthanide elements within the thermal interface material. The lanthanide elements can be provided in the thermal interface material to a total concentration of greater than 0 weight percent and less than or equal to about 2 weight percent. In particular aspects, gadolinium is provided in the thermal interface material to a concentration of greater than about 0 weight percent and less than or equal to about 2 weight percent, with a contemplated concentration being from about 0.5 weight percent to about 2 weight percent.

The thermal interface material typically comprises the lanthanide elements dispersed within solder. For instance, a contemplated thermal interface material can comprise, consist essentially of, or consist of an indium/bismuth solder having gadolinium dispersed therein. Such solder can comprise from greater that 0 weight percent to less than or equal to about 50 weight percent bismuth, and in particular aspects can comprise from at least about 5 weight percent to less than or equal to about 50 weight percent bismuth. A contemplated solder can comprise about 33 weight percent bismuth, from about 0.5 weight percent gadolinium to about 2 weight percent gadolinium, and the remainder indium.

Another contemplated solder can comprise, consist essentially of, or consist of indium, silver and gadolinium. The silver can be present in a concentration of from about 0.5 weight percent to about 10 weight percent, and typically will be present to a concentration of about 3 weight percent. The gadolinium can be present to a concentration of from greater than 0 weight percent to less than or equal to about 2 weight percent, and typically will be present to a concentration of from about 0.5 weight percent to less than or equal to about 2 weight percent.

In another embodiment, the thermal interface material can comprise a solder containing tin, indium and zinc; and can have gadolinium dispersed therethrough. The indium can be present to a concentration of from about 5 weight percent to about 50 weight percent, the zinc can be present to a concentration of from about 1 weight percent to about 10 weight percent, the gadolinium can be present to a concentration of from greater than 0 weight percent to about 2 weight percent (and typically to a concentration of from greater than or equal to about 0.5 weight percent to less than or equal to about 2 weight percent), and the remainder of the composition can comprise tin. In a contemplated aspect, the thermal interface material can comprise, consist essentially of, or consist of about 70 weight percent tin, about 25 weight percent indium, about 5 weight percent zinc, and from about 0.5 weight percent to about 2 weight percent gadolinium. In another aspect, the thermal interface material can comprise a solder containing indium, magnesium and zinc; and can have gadolinium dispersed therethrough.

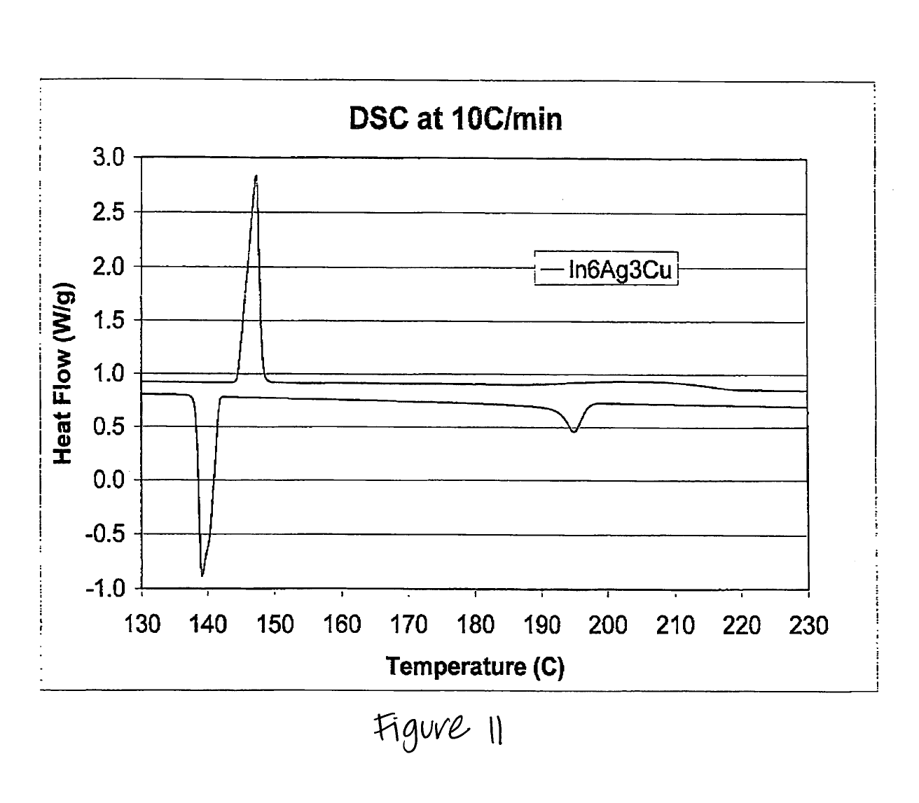

An additional contemplated solder is one that comprises and/or consists essentially of indium, copper and silver. Differential scanning calorimetry (DSC) was run from 100-160° C. at 2° C./min and it was found that this solder melts at about 146° C. during heating. (see FIG. 10) This particular solder freezes at 143° C. during cooling experiments. It is estimated through these experiments that 143° C. is the ternary eutectic for In—Ag—Cu based upon the peaks from 144° C. to 142° C. In6Ag3Cu was cast and tested to determine if the melting behavior is acceptable. DSC at 10° C./min gave sharp peaks in the 138-146° C. range and a broader, smaller peak in the 195-215° C. range. (see FIG. 11) DSC at 2° C./min from 120-160° C. showed very similar peaks to the In3Ag1.5Cu solder alloy. (see FIG. 10) These solder alloys have higher strength and better fatigue resistance than indium solders with the same or possibly higher thermal conductivity. In addition, there is less dissolution of particles on the substrates because of the copper in the solder.

There can be some difficulties in dispersing gadolinium within various solders, in that gadolinium tends to be highly reactive with oxygen. Accordingly, the gadolinium is preferably handled in an inert atmosphere. One method for dispersing gadolinium in a contemplated solder containing indium and bismuth is as follows. Molten solder is provided within an inert atmosphere (with the inert atmosphere specifically being inert relative to oxidation of gadolinium). Gadolinium is then transferred into the molten solder, under the inert atmosphere, and completely encapsulated by the solder. The solder is then cooled. In some aspects, the solder is cooled under the inert atmosphere, and then the solder having the encapsulated gadolinium therein is placed in an induction furnace under a suitable inert atmosphere (such as a nitrogen atmosphere), and heated to a desired temperature to melt the gadolinium into the solder.

The lanthanide elements can be utilized with or without the particles discussed above with reference to FIGS. 1-3. In particular aspects of the subject matter, thermal interface materials can be formed to have one or more lanthanide elements dispersed within a solder to improve wetability to the solder, and to have various high thermal conductivity particles (with “high thermal conductivity particles” being defined as particles having thermal conductivity greater than or equal to about 80 W/m-K) within the solder to improve thermal conductivity of the thermal interface material.

In some embodiments, the subject matter includes solders having eutectic material or material with a lower melting point seeding therein, such as for example, solder ribbons having wires of eutectic seed material extending therein.

A difficulty with metallic solders is the ability to reflow and join the silicon die to adjacent package component, normally a copper or a nickel-plated copper heat spreader, without entrapping air under the die. Even a small amount of trapped air will cause a void that can cause catastrophic failure of the die by localized overheating. In some aspects, the subject matter includes solder compositions and methods of solder preparation designed to alleviate entrapped air and thereby reduce, or even eliminate voiding in solder joints.

When soldering two flat components, it can be desirable to have the liquid solder phase begin at one part edge and melt progressively toward the other edge. If this can be made to happen, air can be displaced as the liquid phase progresses and a continuous solder joint can be formed. Voids and trapped air can thus be minimized in this way. A variant of this approach is to have the melting begin in the center of the solder joint and propagate toward all the edges. Of course, solders do not normally melt this way. Rather, they tend to melt homogenously or at points of contact where heat can flow into the solder. When the solder melts homogenously, it can entrap gasses that are unable to escape when the solder solidifies. In some aspects, the subject matter includes utilization of a solder preform used to attach two or more components of a semiconductor package (such as, for example, to attach a semiconductor die to a heat spreader), with the solder perform ultimately becoming a thermal interface material between the components. In such aspects, the subject matter can including cladding a small amount of eutectic solder to the center of the solder preform. The cladding can be provided during any suitable processing step, but generally will be provided during manufacture of the solder.

The cladding provides a low melting region in the center of the bulk solder preform. During reflow of the solder, the cladded center of the solder melts first to form a liquidus phase, such liquidus phase moves from the center of the preform toward the edges. The liquidus phase displaces air from the solder joint as it propagates.

Solder performs for die attach are normally fabricated as ribbons. The ribbons have thicknesses and widths approximately corresponding to preferred dimensions for the thicknesses and die widths, respectively, of solder joints. The ribbons are cut to desired lengths as part of a semiconductor package assembly process.

Typical dimensions of a solder ribbon can be about 0.006 inches thick and about 0.6 inches wide, in applications where a desired joint thickness is about 0.006 inches and the width of the die to be soldered is about 0.6 inches.

Eutectic solder compositions are alloys of two or more metals that have lower melting points than the metals themselves. A contemplated eutectic solder composition In52%-Sn48% (in other words, 52 weight percent indium and 48 weight percent tin), which melts at 120° C. Pure In melts at 156.6° C. and pure Sn melts at 232° C. The concept of eutectics can be extended beyond pure metals. For instance, a solder composition can be an alloy having a particular melting point, and a eutectic mixture can be formed to contain such composition and to have a melting point lower than the composition itself.

In some aspects, the subject matter as described herein includes formation of a solder ribbon of a first composition which is seeded with a wire of a second composition during production. The second composition is a eutectic or near eutectic with a lower melting point than the first composition. The second composition will alloy with the first composition to, in some cases, form a composition with a melting point that is intermediate between that of the two compositions and in other cases a composition with a melting point that is lower than that of the second composition, i.e. a higher order eutectic composition.

In a specific example, a 0.6 inch solder ribbon might start as 1 inch wide ribbon during rolling. The solder can be an indium-containing composition, such as, for example, a composition consisting essentially, or consisting of indium. A 0.03 inch diameter wire of containing 33.3 weight percent bismuth and 66.7 weight percent indium (eutectic composition, melting point 73° C.) is roll clad into the center (or approximate center) of the ribbon during fabrication. The wire is subsequently crushed into the surface of the ribbon and is thus incorporated into the ribbon. The ribbon is subsequently slit to a desired width, such as, for example, 0.6 inches, with the indium/bismuth composition remaining in about the center of the ribbon.

The ribbon can be subsequently utilized for attachment of components of a semiconductor package. The solder is provided between the components and heated to cause melting and reflow of the solder. The crushed wire seed within the solder melts before the bulk of the solder due to the wire seed having a eutectic composition with a depressed melting point relative to the rest of the solder. Since the crushed seed material is approximately in the center of the solder ribbon, the central portion of the solder ribbon will melt first. Gases and voids within the solder will then be pushed out of the solder as the liquid phase propagates from the central region of the solder toward the edges.

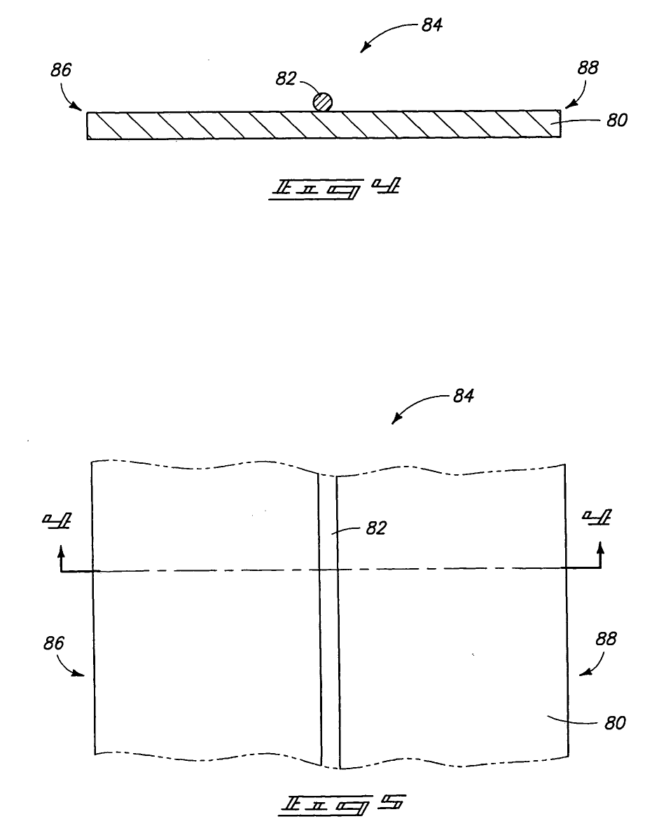

Referring to FIGS. 4 and 5, a solder preform 80 has a wire 82 provided thereover. The solder preform can be, for example, a ribbon. The solder preform comprises a first composition, and the wire comprises a second composition which forms a eutectic mixture with the first composition upon melting of the solder. The preform and wire can together be referred to as a solder preform construction 84. Although the second composition is described to be in a shape of a wire, it is to be understood that the second composition can be provided to be as a structure of any suitable shape. Also, although only one wire of the second composition is shown being used in the construction 84, it is to be understood that multiple wires, or other shapes, of the second composition can be utilized in a solder preform construction.

The solder of FIGS. 4 and 5 has a pair of opposing edges 86 and 88, and in the shown application of the subject matter the structure 82 is approximately centrally located between the opposing edges.

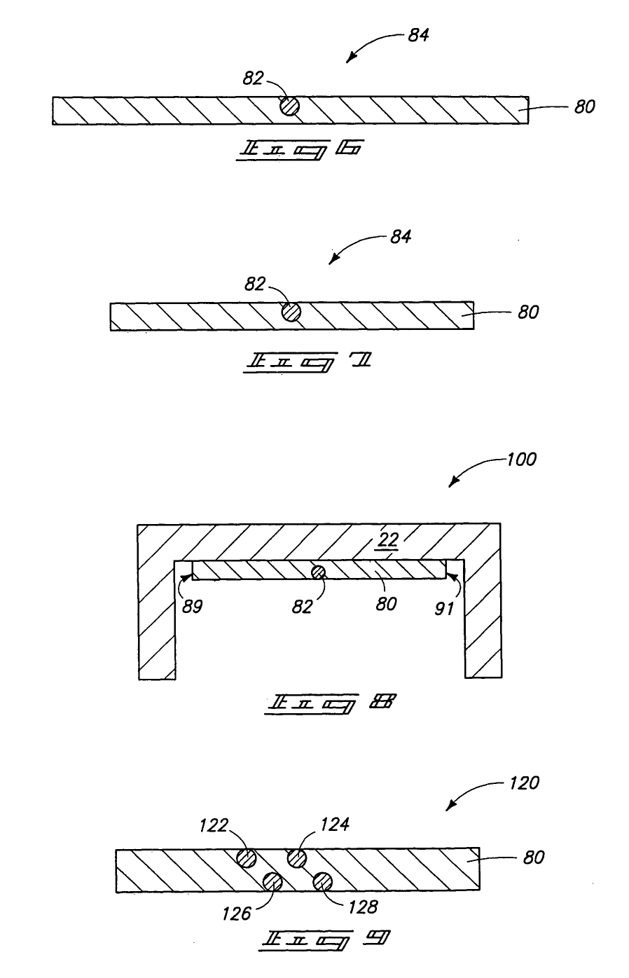

Referring to FIG. 6, the wire 82 is crushed into the solder 80.

Referring to FIG. 7, the solder preform construction is shown after it has been cut to a desired width. In the shown application, the width of the solder is the same as that of the thermal interface material 28 of FIG. 1, and accordingly the solder can be used for such thermal interface material and specifically used to connect a heat sink to a heat spreader in a semiconductor package. Alternatively, the solder could be cut to a desired width to be used for the thermal interface material 24 of FIG. 1 and used to connect a heat spreader to a semiconductor die.

Although the methodology of FIGS. 4-7 provides a eutectic material composition within the solder preform by pressing a wire of the eutectic material composition into the solder, it is to be understood that the subject matter encompasses other methods for providing structures of eutectic material compositions within solder to form solder preform constructions analogous to the constructions of FIGS. 6 and 7. Such other methods can include, for example, co-extrusion of the eutectic material composition and the solder.

Solder perform constructions having depressed melting point seeds therein can be used in numerous applications, with typical applications being associated with the fabrication of semiconductor packages. For instance, as discussed above, the perform constructions can be utilized for attaching a heat spreader to a package. In such applications, the solder can be pre-attached to a heat spreader, and the assembly of the heat-spreader with pre-attached solder could be commercially supplied to end users rather than providing the users with the heat spreader and solder ribbon separately. This could be valuable to the end users in that it would potentially save fabrication steps involved in attaching solder to heat spreaders.

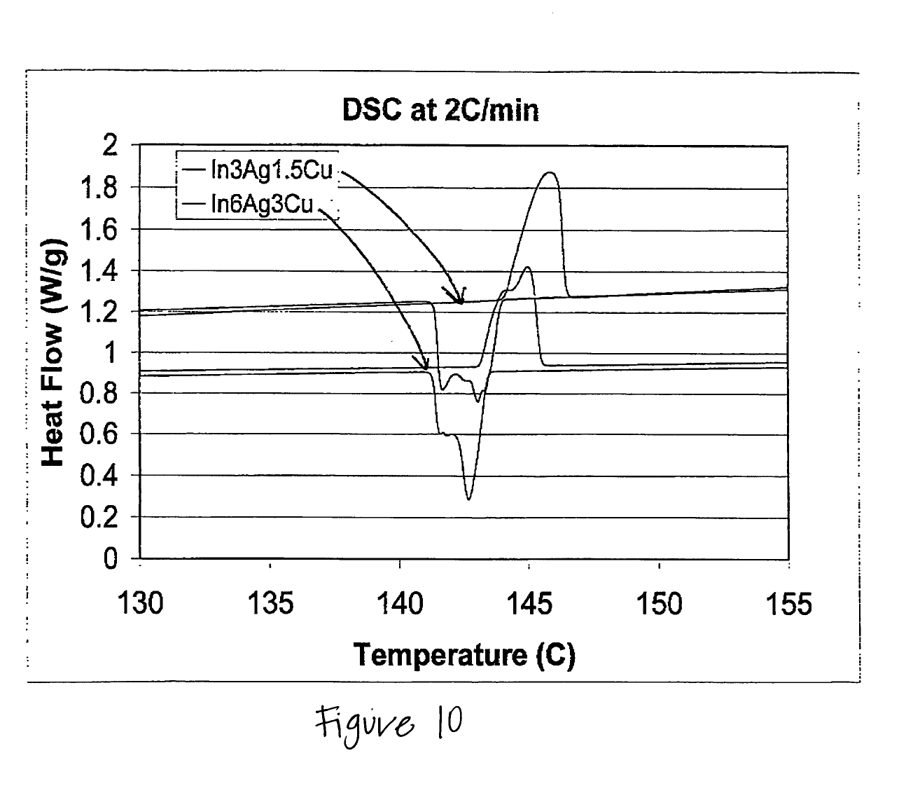

FIG. 8 shows a contemplated assembly 100 comprising a heat spreader 22 of the type shown in FIG. 1 bonded to a solder preform 84 of the type described in FIG. 7. The solder is shown having a pair of edges 89 and 91, and a width between the edges.

In some aspects, the solder can be bonded to the spreader by melting at least some of the solder. In such aspects, the second composition of structure 82 may partially disperse into the solder, so that the structure 82 becomes less defined than it had been in the solder preform before bonding of the preform to the heat spreader. However, it can be advantageous if the second composition still remains as a detectable region within the solder preform rather than becoming homogeneously distributed throughout the solder preform in that the second composition can then still lower the melting point of such region relative to the bulk of the solder preform. Preferably, the region of the second composition will be substantially centralized between the edges 89 and 91 of the solder.

There are numerous modifications that could be made to the solder/seed performs discussed above. For instance, the solder could be seeded on both sides with different metals. This could, in some aspects, improve the substantially void-free attachment of the solder to components on either side of the solder (such as, for example, a heat spreader on one side and a silicon die on the other side) by tailoring the properties of the solder on each side for the component that the solder will bond to on the respective sides. FIG. 9 shows a solder preform construction 120 comprising solder 80 of a first composition having four wires 122, 124, 126 and 128 of eutectic materials provided therein. The wires can have all have the same composition, or at least one of wires can have a different composition relative to the others. In other words, a solder preform construction of the present subject matter can include solder 80 having a plurality of structures 122, 124, 126 and 128 therein, with the structures comprising one or more compositions eutectic with the first composition. In some aspects at least one of the structures can be of the same composition as at least one other of the structures, and in other aspects at least one of the structures can be of a different composition than at least one other of the structures. In particular aspects, the structures 122 and 124 on the same side of the thickness of solder 80 are the same in composition as one another, and the structures 126 and 128 on the other side of the thickness from the structures 122 and 124 are of a different composition than the structures 122 and 124.

Any suitable seed materials can be chosen for incorporation into a solder preform construction. Suitability of particular seed materials for particular applications can depend on, for example, melting point depression achieved with the materials and the processing temperatures that the materials will be exposed to. In exemplary aspects in which the bulk solder of a solder perform is primarily indium, the seed materials clad to the preform can be selected from the group of consisting of bismuth, silver, lead, tin, zinc, and mixtures thereof. The melting point depression and physical properties associated with bismuth, tin and silver can make these metals particularly good choices for utilization with bulk solders comprising at least about 65 weight percent indium, including bulk solders consisting essentially of or consisting of indium.

The solder preform constructions have melting point depressing seeds therein can also have particles therein of the type described with reference to FIGS. 1-3, and/or can have one or more lanthanide elements therein to improve wetability of the solder preform constructions on various materials utilized in semiconductor packages.

Thus, specific embodiments and applications of thermal interface materials and methods of use and production thereof have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A thermally conductive material comprising an alloy which includes indium, zinc, magnesium or a combination thereof.

2. The thermally conductive material of claim 1, further comprising at least one of silver, copper or tin.

3. The thermally conductive material of claim 2, comprising particles dispersed throughout the alloy, the particles being of thermal conductivity greater than or equal to about 80 W/m-K.

4. The thermally conductive material of claim 1, wherein the alloy consists essentially of the indium, zinc and magnesium.

5. The thermally conductive material of claim 1, wherein the zinc is provided to a concentration of from greater than about 0 weight % to less than or equal to about 5 weight %, and wherein the magnesium is provided to a concentration of from greater than about 0 weight % to less than or equal to about 0.5 weight %.

6. The thermally conductive material of claim 5, comprising particles dispersed throughout the alloy, the particles being of thermal conductivity greater than or equal to about 80 W/m-K.

7. The thermally conductive material of claim 1, wherein the alloy consists essentially of indium, zinc, magnesium and at least one lanthanide element.

8. The thermally conductive material of claim 7, wherein the at least one lanthanide element includes gadolinium.

9. The thermally conductive material of claim 8, comprising particles dispersed throughout the alloy, the particles being of thermal conductivity greater than or equal to about 80 W/m-K.

10. The thermally conductive material of claim 1, wherein the alloy consists essentially of indium, zinc, magnesium, at least one lanthanide element, and one or both of silver and tin.

11. A semiconductor package comprising a thermal interface material which includes solder and particles dispersed throughout the solder, the particles being of thermal conductivity greater than or equal to about 80 W/m-K.

12. The semiconductor package of claim 11, wherein the particles are of thermal conductivity greater than or equal to about 200 W/m-K.

13. The semiconductor package of claim 11, wherein the particles have a maximum dimension of less than or equal to about 0.005 inches.

14. The semiconductor package of claim 13, wherein the particles have a maximum dimension of less than or equal to about 0.002 inches.

15. The semiconductor package of claim 14, wherein the particles have a maximum dimension of less than or equal to about 0.001 inches.

16. The semiconductor package of claim 11, wherein the particles comprise at least one of aluminum, copper, nickel and silver.

17. The semiconductor package of claim 11, wherein the particles consist essentially of at least one of aluminum, copper, nickel and silver.

18. The semiconductor package of claim 11, wherein the particles consist essentially of carbon.

19. The semiconductor package of claim 11, wherein the particles comprise a nickel coating around a thermally conductive core that comprises a different composition than the nickel coating.

20. The semiconductor package of claim 19, wherein the thermally conductive core consists essentially of aluminum, carbon, copper, silver or a combination thereof.

21. The semiconductor package of claim 11, wherein the solder comprises at least one lanthanide element to a total concentration of the at least one lanthanide element of less than or equal to about 2 weight percent.

22. The semiconductor package of claim 11, wherein the solder comprises gadolinium to a concentration of less than or equal to about 2 weight percent.

23. The semiconductor package of claim 22, wherein the solder comprises indium, zinc, magnesium or a combination thereof.

24. The semiconductor package of claim 22, wherein the solder comprises indium, bismuth or a combination thereof.

25. The semiconductor package of claim 24, wherein the bismuth is present to a concentration of from about 5 weight percent to about 50 weight percent.

26. The semiconductor package of claim 22, wherein the solder comprises indium, silver or a combination thereof.

27. The semiconductor package of claim 26, wherein the silver is present to a concentration of from about 2 weight percent to about 25 weight percent.

28. The semiconductor package of claim 22, wherein the solder comprises indium, tin, zinc or a combination thereof.

29. The semiconductor package of claim 22, wherein the gadolinium concentration is greater than about 0.5 weight percent.

30. The semiconductor package of claim 11, wherein the solder comprises an alloy comprising a metallic material; and wherein the particles comprise the metallic material in elemental form.

31. The semiconductor package of claim 11, wherein the solder comprises an alloy containing indium, silver or a combination thereof; and wherein the particles comprise silver.

32. The semiconductor package of claim 11, wherein the thermal interface material is between a semiconductor die and a heat spreader.

33. The semiconductor package of claim 11, wherein the thermal interface material is between a heat spreader and a heat sink.

34. A semiconductor package comprising a thermal interface material which includes at least one lanthanide element.

35. The package of claim 34, wherein the at least one lanthanide element is present to a total concentration of less than or equal to about 2 weight percent.

36. The package of claim 34, wherein the at least one lanthanide element includes gadolinium.

37. The package of claim 34, wherein the at least one lanthanide element consists essentially of gadolinium.

38. The semiconductor package of claim 34, wherein the at least one lanthanide element is dispersed within a solder.

39. The semiconductor package of claim 38, further comprising a plurality of particles dispersed within the solder, the particles being of thermal conductivity greater than or equal to about 80 W/m-K and comprising maximum dimensions of less than 0.001 inches.

40. The semiconductor package of claim 39, wherein the particles comprise aluminum, carbon, copper, nickel, silver or a combination thereof.

41. The semiconductor package of claim 38, wherein the solder comprises indium, bismuth or a combination thereof.

42. The semiconductor package of claim 38, wherein the solder comprises indium, silver or a combination thereof.

43. The semiconductor package of claim 38, wherein the solder comprises indium, tin, zinc or a combination thereof.

44. The semiconductor package of claim 38, wherein the solder comprises indium, zinc, magnesium or a combination thereof.

45. The semiconductor package of claim 34, wherein the thermal interface material is between a semiconductor die and a heat spreader.

46. The semiconductor package of claim 34, wherein the thermal interface material is between a heat spreader and a heat sink.

47. A solder preform construction comprising a solder and a structure within the solder, the solder being of a first composition and the structure being of a second composition which has a lower melting point than the first composition.

48. The construction of claim 47, wherein the first composition comprises at least 60 weight percent indium and the second composition comprises bismuth, silver, lead, tin, zinc or a combination thereof.

49. The construction of claim 47, wherein the solder is a ribbon having a width between opposing first and second edges, and wherein the structure is approximately centrally located between the first and second edge.

50. The construction of claim 47, comprising particles dispersed throughout the solder, with the particles being of thermal conductivity greater than or equal to about 80 W/m-K.

51. The construction of claim 47, comprising at least one lanthanide element dispersed throughout the solder.

52. The construction of claim 47 comprising:
particles dispersed throughout the solder, with the particles being of thermal conductivity greater than or equal to about 80 W/m-K; and
gadolinium dispersed throughout the first composition of the solder.

53. An assembly comprising:
a heat spreader; and
a solder preform construction bonded to the heat spreader, the solder preform construction comprising a solder of a first composition, and a region within the solder of a second composition which has a lower melting point than the first composition.

54. The assembly of claim 53, wherein the solder has a pair of opposing edges and a width between such edges, and wherein the region is substantially centralized within such width.

55. The assembly of claim 53, wherein the first composition comprises at least 60 weight percent indium and the second composition comprises bismuth, silver, lead, tin, zinc or a combination thereof.

56. The assembly of claim 53, comprising particles dispersed throughout the solder, with the particles being of thermal conductivity greater than or equal to about 80 W/m-K.

57. The assembly of claim 53, comprising at least one lanthanide element dispersed throughout the solder.

58. The assembly of claim 53, comprising:
particles dispersed throughout the solder, with the particles being of thermal conductivity greater than or equal to about 80 W/m-K; and
gadolinium dispersed throughout the first composition of the solder.
